(19) United States
(12) Patent Application Publication
(10) Pub. No.: US 2025/0081408 A1
(43) Pub. Date: Mar. 6, 2025

(54) Fan efficiency control method and server

(71) Applicants: Inventec (Pudong) Technology Corp., Shanghai (CN); Inventec Corporation, Taipei (TW)

(72) Inventors: Chien-Ming Lee, Taipei (TW); Kai-Yang Tung, Taipei (TW)

(73) Assignees: Inventec (Pudong) Technology Corp., Shanghai (CN); Inventec Corporation, Taipei (TW)

(21) Appl. No.: 18/597,937

(22) Filed: Mar. 7, 2024

(30) Foreign Application Priority Data
Aug. 29, 2023 (CN) 202311103444.3

(51) Int. Cl. H05K 7/20; F04D 25/16; F04D 27/00

(52) U.S. Cl. CPC H05K 7/20836; F04D 25/166; F04D 27/00; H05K 7/20736

(57) ABSTRACT

A fan efficiency control method, for a server, wherein the server comprises a plurality of fans and at least one sensor, the fan efficiency control method includes determining a plurality of system parameters of the plurality of fans of the server; obtaining a current temperature through the at least one sensor, and obtaining a temperature parameter corresponding to a main heat source of the server according to the current temperature; obtaining a modulation function; calculating a speed weight of each fan of the plurality of fans according to the plurality of system parameters, the modulation function and the temperature parameter; and adjusting a speed of one of the plurality of fans according to the speed weight.

### BACKGROUND OF THE INVENTION

### 1. Field of the Invention

The present invention relates to a fan efficiency control method and a server, and more particularly, to a fan efficiency control method and a server that dynamically adjust the fan speed weight according to a modulation function.

### 2. Description of the Prior Art

Data centers are constructed with energy-intensive facilities. In particular, with the advent of advanced technologies such as artificial intelligence (AI), cloud service, 5G networks and internet of things (IoT), the huge demand for servers brings considerable power consumption. Therefore, “power efficiency” has become a crucial factor in the design of servers. A server is usually equipped with 4 to 10 cooling fans, each of which can consume as much as 100 W or more. The power consumption of the cooling fan increases almost cubically with the speed of the fan. In other words, when the fan speed is excessively high, the overall power consumption of the server will be significantly increased.

Under such circumstances, how to dynamically adjust the fan speed of the server and operate the fan at the optimal efficiency has become one of the goals of the industry.

### SUMMARY OF THE INVENTION

Therefore, the purpose of the present invention is to provide a fan efficiency control method and a server to solve the above problem.

The embodiment of the present invention discloses a fan efficiency control method, for a server, wherein the server comprises a plurality of fans and at least one sensor, the fan efficiency control method comprises: determining a plurality of system parameters of the plurality of fans of the server; obtaining a current temperature through the at least one sensor, and obtaining a temperature parameter corresponding to a main heat source of the server according to the current temperature; obtaining a modulation function; calculating a speed weight of each fan of the plurality of fans according to the plurality of system parameters, the modulation function and the temperature parameter; and adjusting a speed of one of the plurality of fans according to the speed weight.

The embodiment of the present invention discloses a server, comprises: a plurality of fans; at least one sensor; a plurality of proportional integral derivative controller, coupled to the plurality of fans; and a processor, coupled to the sensor and the plurality of proportional integral derivative controller, configured to execute a fan efficiency control method, wherein the fan efficiency control method comprises: determining a plurality of system parameters of the plurality of fans of the server; obtaining a current temperature through the at least one sensor, and obtaining a temperature parameter corresponding to a main heat source of the server according to the current temperature; obtaining a modulation function; calculating a speed weight of each fan of the plurality of fans according to the plurality of system parameters, the modulation function and the temperature parameter; and adjusting, by the plurality of proportional integral derivative controller, a speed of one of the plurality of fans according to the speed weight.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A is a schematic diagram of a server according to an embodiment of the present invention.

FIG. 1B is a schematic diagram of the layout inside the chassis of the server.

FIG. 2 is a flowchart of the fan efficiency control method according to an embodiment of the present invention.

FIG. 3 is a schematic diagram of the server according to an embodiment of the present invention.

FIG. 4 is a schematic diagram of a modulation function according to an embodiment of the present invention.

FIG. 5 is a schematic diagram of the graphical model of the fan efficiency control method of the embodiment of the present invention.

FIG. 6A-6C are schematic diagrams of the power consumptions of the plurality of fans F1-F6 when adopting the conventional technology.

FIG. 7A-7C are the schematic diagrams of the power consumptions of the plurality of fans according to the embodiments of the present invention.

### DETAILED DESCRIPTION

Certain terms are used throughout the description and following claims to refer to particular components. As one skilled in the art will appreciate, hardware manufacturers may refer to a component by different names. This document does not intend to distinguish between components that differ in name but not function. In the following description and in the claims, the terms “include” and “comprise” are utilized in an open-ended fashion, and thus should be interpreted to mean “include, but not limited to”. Also, the term “couple” is intended to mean either an indirect or direct electrical connection. Accordingly, if one device is coupled to another device, that connection may be through a direct electrical connection, or through an indirect electrical connection via other devices and connections.

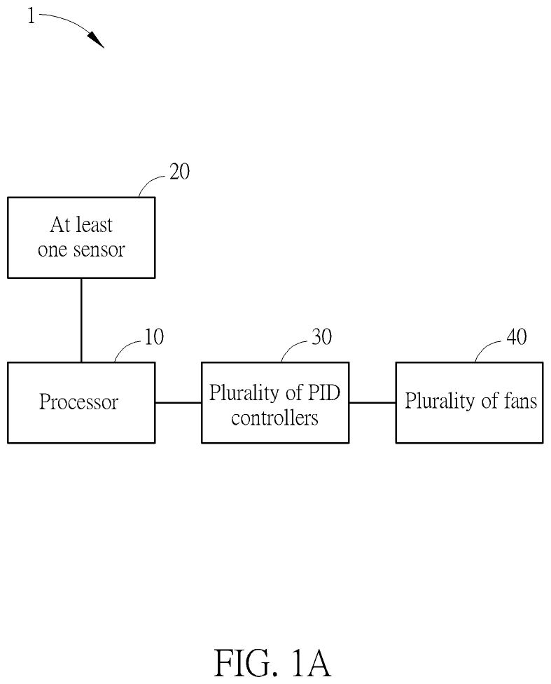

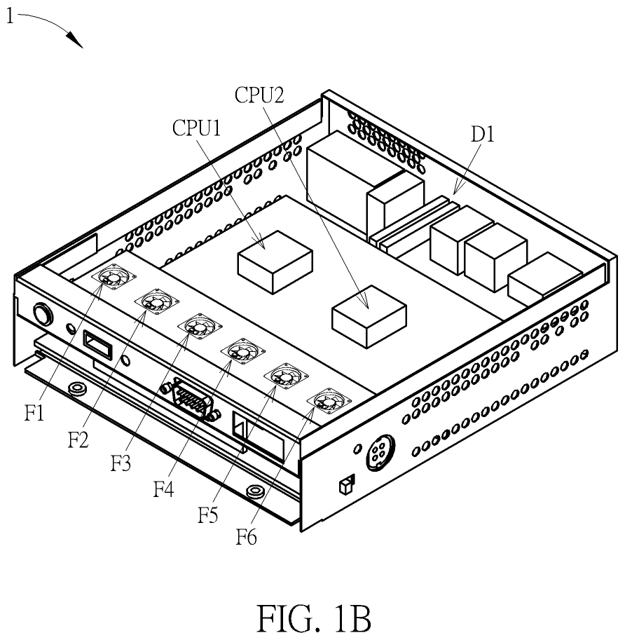

Please refer to FIG. 1A. FIG. 1A is a schematic diagram of a server 1 according to an embodiment of the present invention. The server 1 includes a processor 10, at least one sensor 20, a plurality of proportional-integral-derivative (PID) controllers 30 and a plurality of fans 40. The processor 10 is coupled to the at least one sensor 20 and the plurality of PID controllers 30, and configured to execute a fan efficiency control method to dynamically adjust the fan speed of the plurality of fans 40 in the server 1 and control the plurality of fans 40 to operate at an optimal efficiency respectively. It should be noted that, the server 1 represents the necessary components required to the fan efficiency control method, and its basic structure is well known in the art, and will not be narrated for brevity. Those skilled in the art may add other components as needed, such as the motherboard, the power supply, the memory, the central processing unit (CPU), the graphics processing unit (GPU), etc., but not limited thereto, or may implement the server 1 with appropriate devices or equipment. For example, please refer to FIG. 1B. FIG. 1B is a schematic diagram of a layout inside the chassis of the server 1. The server 1 includes two CPUs (CPU1, CPU2), the memory D1, six fans (F1-F6) and the at least one sensor (not shown in FIG. 1B). Specifically, when the server 1 is operating, the two CPUs (CPU1, CPU2) and the memory D1 may generate a large amount of thermal energy, and the processor 10 performs the fan efficiency control method to dynamically adjust the fan speed of the six fans (F1-F6) and make the six fans (F1-F6) operate at the optimal efficiency.

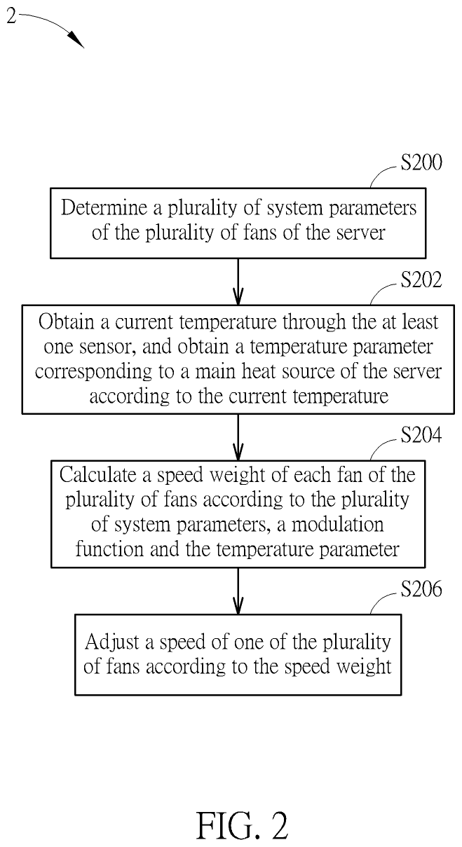

The fan efficiency control method performed by the processor 10 may be summarized as a process 2, as shown in FIG. 2. The process 2 includes the following steps:

Step S200: Determine a plurality of system parameters of the plurality of fans of the server.

Step S202: Obtain a current temperature through the at least one sensor, and obtain a temperature parameter corresponding to a main heat source of the server according to the current temperature.

Step S204: Calculate a speed weight of each fan of the plurality of fans according to the plurality of system parameters, a modulation function and the temperature parameter.

Step S206: Adjust a speed of one of the plurality of fans according to the speed weight.

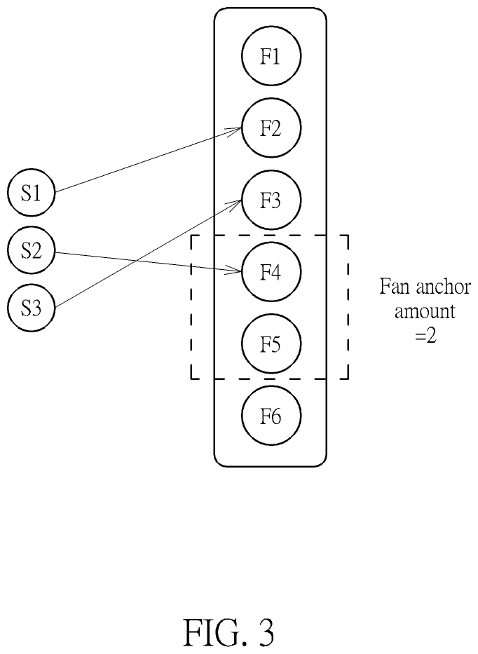

According to the process 2, in step S200, the processor 10 obtains the plurality of system parameters of the plurality of fans 40 of the server. The plurality of system parameters may include a fan amount, a distance between each fan, etc., but not limited thereto. For example, please refer to FIG. 3. FIG. 3 is a schematic diagram of a server 3 according to an embodiment of the present invention. The server 3 includes a plurality of fans F1-F6 and a plurality of sensors S1-S3. It should be noted that the plurality of sensors S1-S3 correspond to a plurality of main heat sources of the server 3, such as the CPU, dual in-line memory (DIMM) and the GPU, etc., but not limited thereto. In addition, the processor 10 may dynamically adjust the fan speed of the plurality of fans 40 for the plurality of main heat sources, and operate the plurality of fans 40 at optimal efficiency. It should be noted that, FIG. 3 is only the embodiment of the present invention, and those skilled in the art may adjust the fan amount and the sensor amount according to the system requirements. For the sake of illustration, the concept of the present invention is illustrated below with a main heat source of the server and its corresponding sensor S2.

In an embodiment, the fan amount of the server 3 is 6. The processor 10 determines a fan anchor and a fan anchor amount according to the distance between the sensor S2 and the fans F1-F6. For example, the sensor S2 is closest to the fan F4, and the processor 10 may determine that the fan F4 is the fan anchor. Furthermore, the fan anchor amount may be set to 2, so the processor 10 determines that the fan F5 below the fan F4 is also the fan anchor. In other words, for the heat dissipation of the main heat sources, the fan F4 and the fan F5 are two primary fans, while the fans F1-F3, F6 are four secondary fans. It should be noted that, the fan anchor amount is related to the computing amount of the processor 10, and those skilled in the art should appropriately increase the fan anchor amount according to the requirements.

In step S202, the processor 10 obtains a temperature parameter corresponding to a main heat source of the server. In detail, the sensor S2 may sense a current temperature of the main heat source. In this way, the processor 10 may determine the temperature parameter of the main heat source according to the current temperature and a setup temperature corresponding to the main heat source. For example, the temperature parameter is the difference between the setup temperature and the current temperature, that is, the temperature error, wherein the setup temperature is, for example, defined by the thermal table.

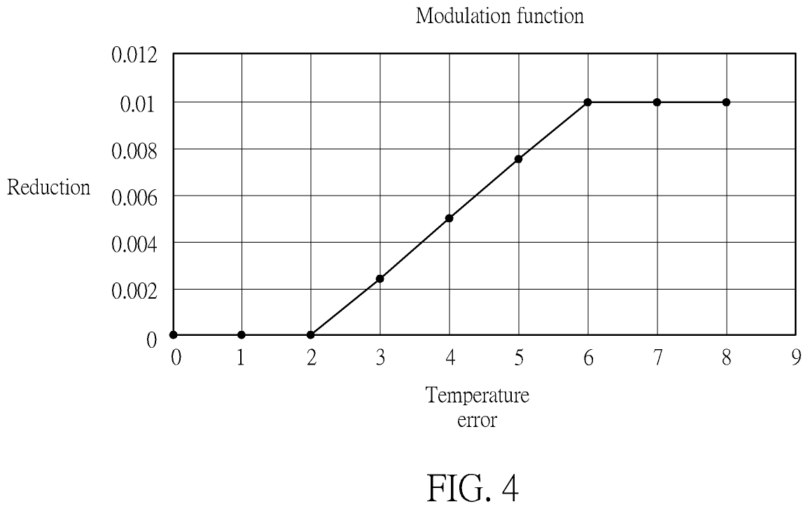

In step S204, the processor 10 may set up a plurality of initial weights corresponding to the plurality of fans F1-F6. In this way, the processor 10 may calculate the plurality of speed weights corresponding to the plurality of fans F1-F6 according to the plurality of system parameters, a modulation function and the temperature parameter. The modulation function is used to correct the fan vector, and the modulation function may be customized by the designer and stored in the server 1. Please refer to FIG. 4. FIG. 4 is a schematic diagram of the modulation function according to an embodiment of the present invention. As shown in FIG. 4, when the temperature error is between 2° to 6° Celsius, the temperature error is linearly related to the reduction of the speed weight. For example, when the temperature error is 6° Celsius, the processor 10 may subtract the speed weight by 0.01, which is 18. It should be noted that, the modulation function of FIG. 4 is the embodiment of the present invention, and those skilled in the art may make different modifications accordingly, which is not limited thereto. Furthermore, for heat dissipation of the main heat source, the fan F4 and the fan F5 are two primary fans, so the processor 10 determines to maintain the initial weights of the fan F4 and the fan F5. On the other hand, the processor 10 adjusts the speed weight of the secondary fans (fans F1-F3 and fan F6) according to the modulation function and the temperature error. For example, the plurality of initial weights of the plurality of fans F1-F6 are all equal to 1, which may be expressed as the initial weight vector W₀=[1, 1, 1, 1, 1, 1], and the adjusted speed weight vector W₁ may be expressed as W₁=[w₁,w ₂, w₃, 1, 1, w₆]. In other words, after the adjustment, the speed weights of the fan F4 and the fan F5 maintain at the initial weight equal to 1. In this way, the processor 10 may dynamically reduce the speed weight of the secondary fans, so that the plurality of fans F1-F6 operate at the optimal efficiency. It should be noted that, the plurality of fans F1-F6 and the plurality of speed weights of the above-mentioned embodiment are one-to-one relationships, and those skilled in the art may make different modifications accordingly, which is not limited thereto. For example, the fans F1, F2 correspond to the first speed weight, the fans F3, F4 correspond to the second speed weight, and the fans F5, F6 correspond to the third speed weight.

In step S206, the processor 10 adjusts the fan speed corresponding to one fan of the plurality of fans by the plurality of PID controller 30 according to the plurality of speed weights. In detail, after the processor 10 obtains the temperature parameter or calculates the temperature error, the PID controller 30 may obtain a required speed according to the temperature error. In this way, the processor 10 may dynamically adjust the fan speed of the plurality of fans F1-F6 according to the required speed and the adjusted speed weight vector Wi respectively. For example, the processor 10 obtains the temperature error e from the sensor S2 corresponding to the main heat source and calculates to obtain the speed weight vector W₁=[w₁, w₂, w₃, 1, 1, w₆]. The plurality of PID controller 30 calculate the required speed u₂ according to the temperature error e₂. In this way, the processor 10 may adjust the fan speeds of the plurality of fans F1-F6 as u₂*W₁ respectively through the plurality of PID controllers 30, so that the fan speeds of the plurality of fans F1-F6 operate at the optimal efficiency.

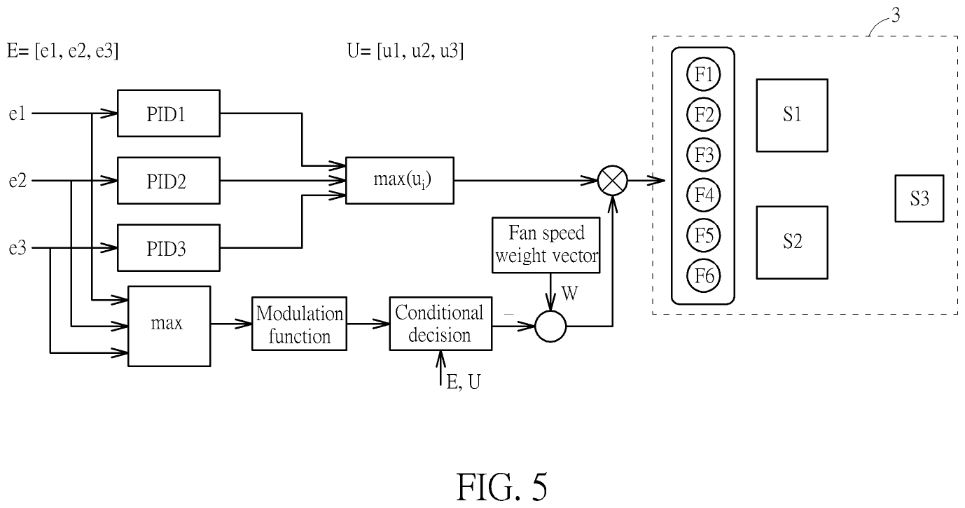

In an embodiment, please refer to FIG. 5. FIG. 5 is a schematic diagram of the graphical model of the fan efficiency control method according to an embodiment of the present invention. In detail, the server 3 includes three sensor S1-S3 corresponding to the three main heat sources of the server. The processor 10 obtains the temperature errors e₁, e₂, e₃ from the sensor S1-S3. The PID controllers PID1-PID3 calculate the required speeds u₁, u₂, u₃ according to the temperature error e₁, e₂, e₃ and express as the required speed vector U=[u₁, u₂, u₃]. The processor 10 may adjust the fan speeds of the plurality of fans F1-F6 as U*W₁ respectively, and operate the plurality of fans F1-F6 at the optimal efficiency.

Furthermore, please refer to FIG. 5. Step 204 of the process 2 may include a conditional decision-making mechanism, which determines whether to adjust the plurality of speed weights of the plurality of fans by determining whether the temperature parameter and the required speed meet an adjustment condition. In an embodiment, the processor 10 may determine whether the temperature parameter is lower than a fist threshold, and determine whether the plurality of required speeds are greater than a second threshold. When the temperature parameter is lower than the first threshold and the plurality of required speeds are greater than the second threshold, the processor 10 calculates the plurality of speed weights according to the modulation function and the plurality of speed weights. When the temperature parameter is greater than or equal to the first threshold or the plurality of required speeds are lower than or equal to the second threshold, the processor 10 maintains the plurality of speed weights as the plurality of initial speed weights. For example, when the temperature error e₂ is lower than 1° Celsius and the required speed u₂ is greater than 50% of a maximum fan speed, the processor 10 calculates the plurality of speed weights according to the modulation function and the plurality of initial speed weights. In this way, the processor 10 may set the fan speeds of the plurality of fans according to the adjusted speed weight or the initial speed weights that are unadjusted, and operates the plurality of fans at the optimal efficiency.

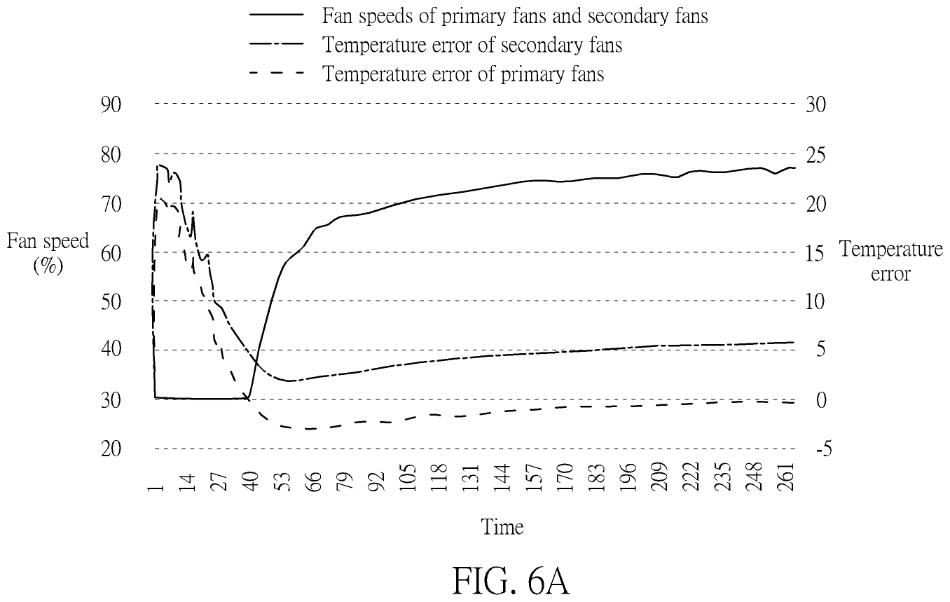

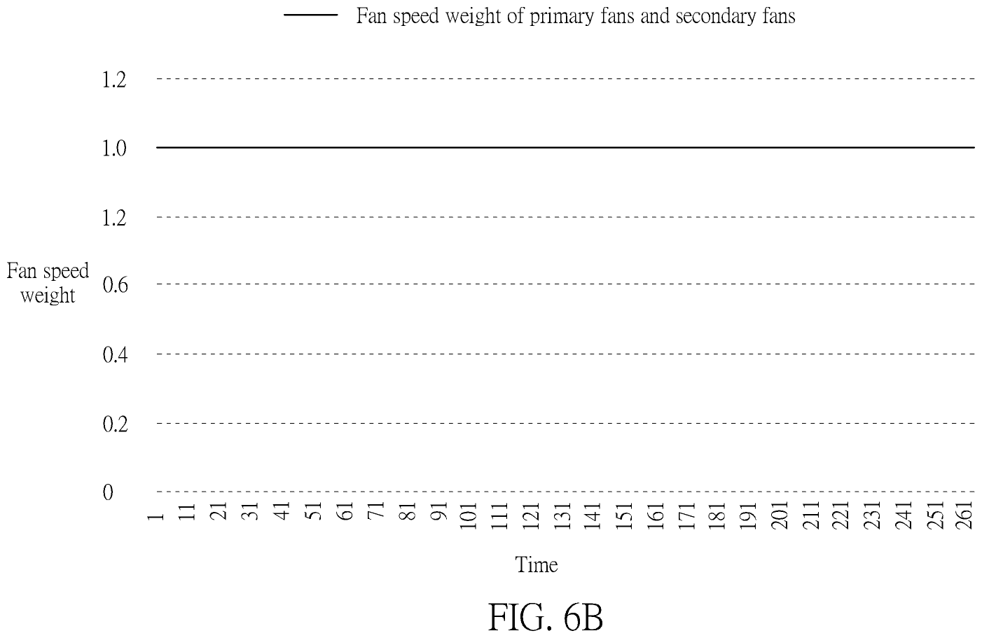

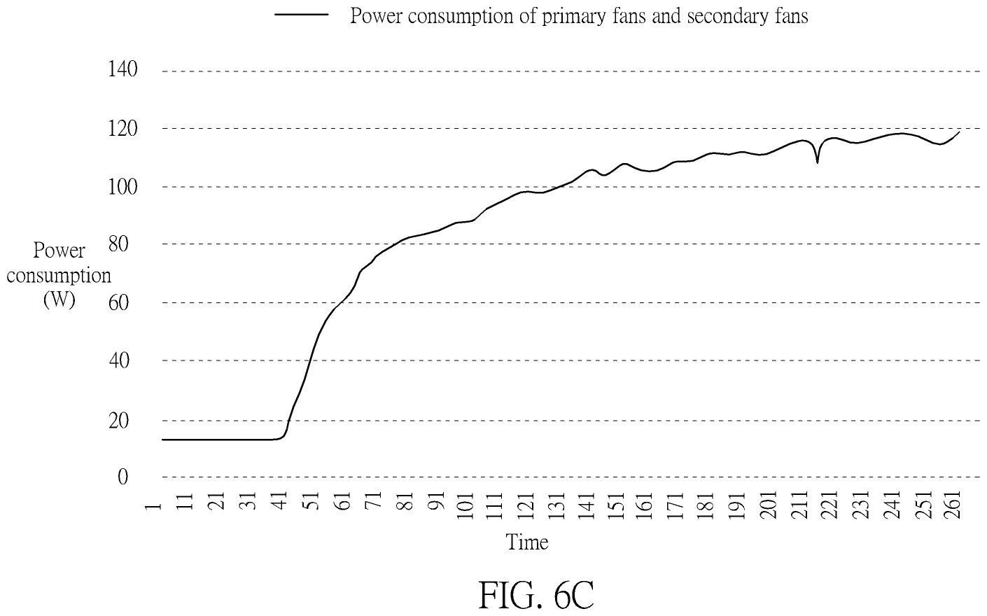

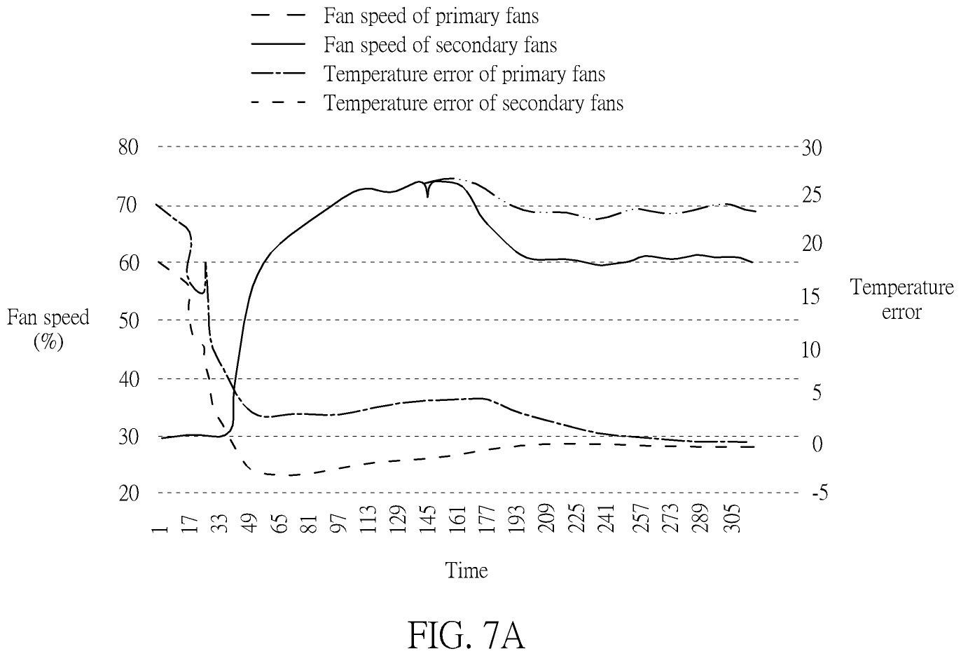

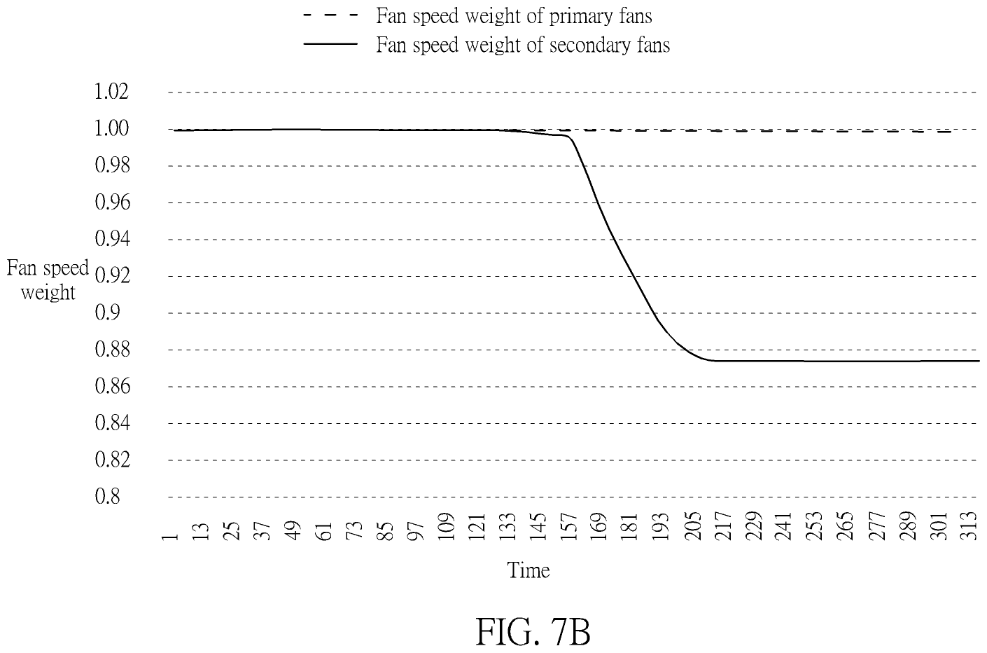

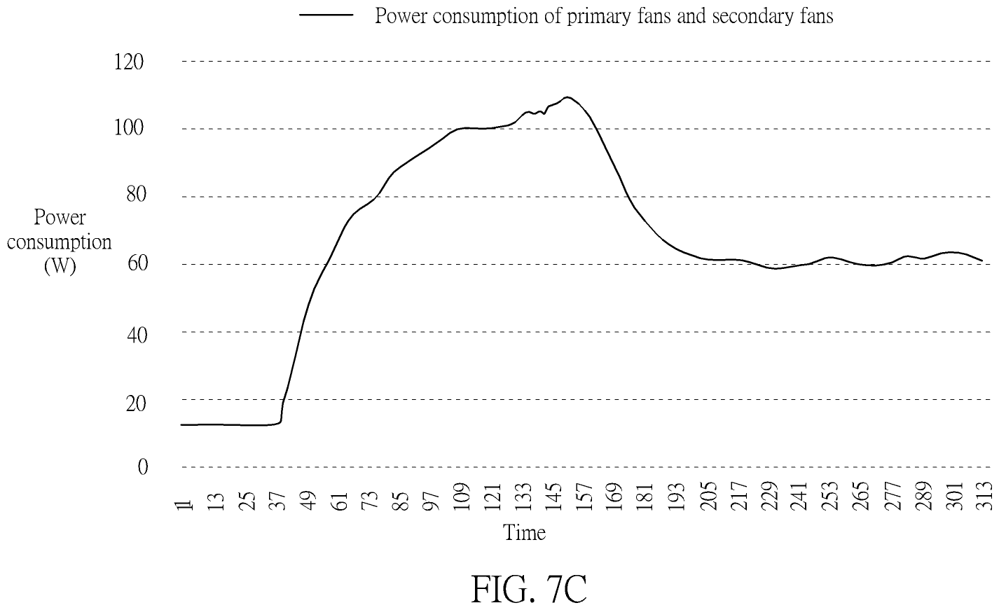

For the power consumption of the plurality of fans F1-F6 of the server 3, please refer to FIG. 6A-6C and FIG. 7A-7C. FIG. 6A-6C are schematic diagrams of the power consumptions of the plurality of fans F1-F6 when adopting the conventional technology. FIG. 7A-7C are schematic diagrams of the power consumptions of the plurality of fans F1-F6 according to the embodiments of the present invention. In detail, the plurality of fans F1-F6 of the server 3 may be divided into the primary fans and the secondary fans. As shown in FIG. 6A, in the conventional technology, after the primary fans and the secondary fans have been running in a synchronized mode for a period of time, the temperature errors of the primary fans and the secondary fans tend to stabilize, so that the fan speeds of the primary fans and the secondary fans are stable to between 75% to 80% of the duty cycle. It should be noted that, as shown in FIG. 6B, in the conventional technology, the speed weights of all fans are 1 and do not change, so the power consumptions of the plurality of fans F1-F6 will be stabilized to 120 W as shown in FIG. 6C. In comparison, the processor 10 of the present invention may adjust the speed weights of the primary fans and the secondary fans, so that the primary fans and the secondary fans operate at the optimal efficiency. For example, as shown in FIGS. 7A-7B, in the embodiment of the present invention, after 140 seconds of the operation of the server 3, the speed weights of the secondary fans begin to decrease, and finally the fan speeds of the primary fans are stabilized to 70% of the duty cycle and the fan speeds of the secondary fans are stabilized to 60% of the duty cycle. Therefore, as shown in FIG. 7C, the power consumptions of the plurality of fans F1-F6 may be stabilized to 60 W. Compared with the conventional technology, the power consumption of the present invention is reduced by nearly 50%.

It should be noted that the server 1 is the embodiment of the present invention. Those skilled in the art should readily make combinations, modifications and/or alterations on the abovementioned description and examples. The abovementioned description, steps, procedures and/or processes including suggested steps can be realized by means that could be hardware, software, firmware (known as a combination of a hardware device and computer instructions and data that reside as read-only software on the hardware device), an electronic system, or combination thereof. Examples of hardware can include analog, digital and mixed circuits known as microcircuit, microchip, or silicon chip. Examples of the electronic system may include a system on chip (SoC), system in package (SiP), a computer on module (COM) and the server 1. Any of the abovementioned procedures and examples above may be compiled into program codes or instructions that are stored in a memory. The memory may include read-only memory (ROM), flash memory, random access memory (RAM), subscriber identity module (SIM), hard disk, or CD-ROM/DVD-ROM/BD-ROM, but not limited thereto. The processor 10 may read and execute the program codes or the instructions stored in the memory for realizing the abovementioned functions.

In the embodiments of the present invention, the server of the present invention may be used for an artificial intelligence (AI) computing, an edge computing, and may also be used as a 5G server, a cloud server or an internet of vehicle server.

In summary, compared to the prior art, the fan efficiency control method of the present invention dynamically adjusts the speed weights of the plurality of fans of the server, and replaces the complicated weight table setting in the conventional technology through the vector computing. In this way, the plurality of fans operate at the optimal efficiency, and the fan efficiency control method is easier to implement.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A fan efficiency control method, for a server, wherein the server comprises a plurality of fans and at least one sensor, the fan efficiency control method comprising:
determining a plurality of system parameters of the plurality of fans of the server;
obtaining a current temperature through the at least one sensor, and obtaining a temperature parameter corresponding to a main heat source of the according to the current temperature;
obtaining a modulation function;
calculating a speed weight of each fan of the plurality of fans according to the plurality of system parameters, the modulation function and the temperature parameter; and
adjusting a speed of one of the plurality of fans according to the speed weight.

2. The fan efficiency control method of claim 1, wherein the step of obtaining the plurality of system parameters of the plurality of fans comprises:
obtaining a fan amount of the plurality of fans;
obtaining a fan anchor amount; and
defining a part of the plurality of fans as a first fan group and defining another part of the plurality of fans as a second fan group according to the fan anchor amount and the main heat source, wherein an amount of the first fan group is equal to the fan anchor amount.

3. The fan efficiency control method of claim 2, wherein the step of calculating the speed weight of each fan of the plurality of fans according to the plurality of system parameters, the modulation function and the temperature parameter comprises:
determining an initial speed weight of each fan of the plurality of fans respectively;
calculating to obtain the speed weight corresponding to the second fan group according to the modulation function, the temperature parameter and the initial speed weight of each fan of the plurality of fans; and
maintaining the initial speed weight corresponding to the first fan group.

4. The fan efficiency control method of claim 1, wherein the step of obtaining the temperature parameter corresponding to the main heat source of the server comprises:
obtaining the temperature parameter of the main heat source according to the current temperature and a setup temperature corresponding to the main heat source.

5. The fan efficiency control method of claim 1, wherein the step of calculating the speed weight of each fan of the plurality of fans according to the plurality of system parameters, the modulation function and the temperature parameter comprises:
determining an initial speed weight of each fan of the plurality of fans respectively;
calculating a required speed of each fan of the plurality of fans;
determining whether the temperature parameter is lower than a first threshold, and determining whether the required speed of each fan of the plurality of fans is greater than a second threshold;
when the temperature parameter is lower than the first threshold and the required speed of each fan of the plurality of fans is greater than the second threshold, calculating to obtain the speed weight of each fan of the plurality of fans according to the modulation function and the initial speed weight of each fan of the plurality of fans; and
when the temperature parameter is higher or equal to the first threshold or the required speed is smaller or equal to the second threshold, obtaining the speed weight as the initial speed weight.

6. A server, comprising:
a plurality of fans;
at least one sensor;
a plurality of proportional integral derivative controller, coupled to the plurality of fans; and
a processor, coupled to the sensor and the plurality of proportional integral derivative controller, configured to execute a fan efficiency control method, wherein the fan efficiency control method comprises:
determining a plurality of system parameters of the plurality of fans of the server;
obtaining a current temperature through the at least one sensor, and obtaining a temperature parameter corresponding to a main heat source of the server according to the current temperature;
obtaining a modulation function;
calculating a speed weight of each fan of the plurality of fans according to the plurality of system parameters, the modulation function and the temperature parameter; and
adjusting, by the plurality of proportional integral derivative controller, a speed of one of the plurality of fans according to the speed weight.

7. The server of claim 6, wherein the step of obtaining the plurality of system parameters of the plurality of fans comprises:
obtaining a fan amount of the plurality of fans;
obtaining a fan anchor amount; and
defining a part of the plurality of fans as a first fan group and defining another part of the plurality of fans as a second fan group according to the fan anchor amount and the main heat source, wherein an amount of the first fan group is equal to the fan anchor amount.

8. The server of claim 7, wherein the step of calculating the speed weight of each fan of the plurality of fans according to the plurality of system parameters, the modulation function and the temperature parameter comprises:
determining an initial speed weight of each fan of the plurality of fans respectively;
calculating to obtain the speed weight corresponding to the second fan group according to the modulation function, the temperature parameter and the initial speed weight of each fan of the plurality of fans; and
maintaining the initial speed weight corresponding to the first fan group.

9. The server of claim 6, wherein the step of obtaining the temperature parameter corresponding to the main heat source of the server comprises:
obtaining the temperature parameter of the main heat source according to the current temperature and a setup temperature corresponding to the main heat source.

10. The server of claim 6, wherein the step of calculating the speed weight of each fan of the plurality of fans according to the plurality of system parameters, the modulation function and the temperature parameter comprises:
determining an initial speed weight of each fan of the plurality of fans respectively;
calculating a required speed of each fan of the plurality of fans;
determining whether the temperature parameter is lower than a first threshold, and determining whether the required speed of each fan of the plurality of fans is greater than a second threshold;
when the temperature parameter is lower than the first threshold and the required speed of each fan of the plurality of fans is greater than the second threshold, calculating to obtain the speed weight of each fan of the plurality of fans according to the modulation function and the initial speed weight of each fan of the plurality of fans; and
when the temperature parameter is higher or equal to the first threshold or the required speed is smaller or equal to the second threshold, obtaining the speed weight as the initial speed weight.
